(19) United States
(12) Patent Application Publication
(10) Pub. No.: US 2009/0251153 A1
(43) Pub. Date: Oct. 8, 2009

(54) MIMO TESTER

(75) Inventors: GUO-JUN XIE, Shenzhen City (CN); CHO-JU CHUNG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY(ShenZhen) Co., LTD., Shenzhen City (CN); HON HAI PRECISION INDUSTRY CO., LTD., Tu-Cheng (TW)

(21) Appl. No.: 12/195,380

(22) Filed: Aug. 20, 2008

(30) Foreign Application Priority Data
Apr. 2, 2008 (CN) 200810300826.4

(51) Int. Cl. G01R 31/28

(52) U.S. Cl. 324/537

(57) ABSTRACT

A multiple input multiple output (MIMO) tester tests various communication parameters of a MIMO device. The MIMO tester includes a first attenuation circuit, a switch circuit, a controlling circuit, and a divider circuit. The first attenuation circuit adjusts an equivalent resistance of the MIMO tester, wherein the first attenuation circuit is electronically connected to the MIMO device. The switch circuit comprises a plurality of switch elements, wherein each switch element comprises an input end, a first output end and a second output end, wherein the switch circuit is electronically connected to the first attenuation circuit. The controlling circuit controls operation of the switch circuit, wherein the controlling circuit is electronically connected to the switch circuit. The divider circuit electronically connected to the switch circuit receives electronic signals from the MIMO device, divides each electronic signal into a plurality of sub-signals, and sends the sub-signals to at least one test device.

### BACKGROUND

1. Field of the Invention

Embodiments of the present disclosure generally relate to test devices, and more particularly to a MIMO tester for testing multiple input multiple output (MIMO) devices.

2. Description of Related Art

With the spreading use of MIMO devices, ensuring the quality of the MIMO devices have risen accordingly. These MIMO devices have to be run through a variety of tests, such as testing a power, a sensitivity, and flux, for example, of a MIMO device. In order to test the above-mentioned parameters, test operators need to provide a testing environment with a plurality of dividers, a plurality of attenuators, and lots of cables, which increases the cost and the complexity of the testing.

Therefore, a heretofore unaddressed need exists in the industry to overcome the aforementioned deficiencies and inadequacies.

### SUMMARY

A multiple input multiple output (MIMO) tester tests various communication parameters of a MIMO device. The MIMO tester includes a first attenuation circuit, a switch circuit, a controlling circuit, and a divider circuit. The first attenuation circuit adjusts an equivalent resistance of the MIMO tester, wherein the first attenuation circuit is electronically connected to the MIMO device. The switch circuit comprises a plurality of switch elements, wherein each switch element comprises an input end, a first output end and a second output end, wherein the switch circuit is electronically connected to the first attenuation circuit. The controlling circuit controls operation of the switch circuit, wherein the controlling circuit is electronically connected to the switch circuit. The divider circuit electronically connected to the switch circuit receives electronic signals from the MIMO device, divides each electronic signal into a plurality of sub-signals, and sends the sub-signals to at least one test device.

Other objectives, advantages and novel features of the present disclosure will be drawn from the following detailed description of certain inventive embodiments of the present disclosure with the attached drawings, in which:

### BRIEF DESCRIPTION OF THE DRAWINGS

FIG. 1 is a schematic diagram showing an application environment of a MIMO tester in accordance with one embodiment of the present disclosure;

FIG. 2 is a schematic diagram showing one embodiment of functional modules of the MIMO tester in accordance with the present disclosure; and

FIG. 3 is a detailed circuit diagram of one embodiment of the MIMO tester in accordance with the present disclosure.

### DETAILED DESCRIPTION OF CERTAIN INVENTIVE EMBODIMENTS

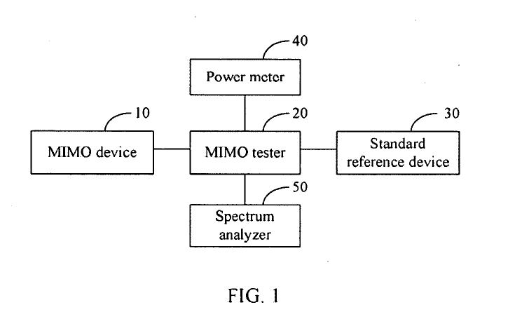

FIG. 1 is a schematic diagram showing an application environment of a MIMO tester 20 in accordance with one embodiment of the present disclosure.

In the embodiment of FIG. 1, the MIMO tester 20 electronically connects to a multiple input multiple output (MIMO) device 10 for testing various communication parameters of the MIMO device 10. A power meter 40 and a spectrum analyzer 50 are both electronically connected to the MIMO tester 20 for testing various power parameters and spectrum parameters of the MIMO device 10. It should be noted that other test devices in addition to the power meter 40 and/or the spectrum analyzer 50 may be connected to the MIMO tester 20 for testing other communication parameters associated with the MIMO device 10, such as sensitivity, and flux, for example.

A standard reference device 30 sends electronic signals to the MIMO device 10 and receives electronic signals from the MIMO device 10. The standard reference device 30 is electronically connected to the MIMO tester 20. In one embodiment, the standard reference device 30 is a MIMO device with specific communication parameters, such as an access point, a wireless router, or a wireless network card, for example. When the MIMO device 10 acts as a sender, the standard reference device 30 receives electronic signals from the MIMO device 10 via the MIMO tester 20. When the MIMO device 10 acts as a receiver, the standard reference device 30 sends electronic signals to the MIMO device 10 via the MIMO tester 20.

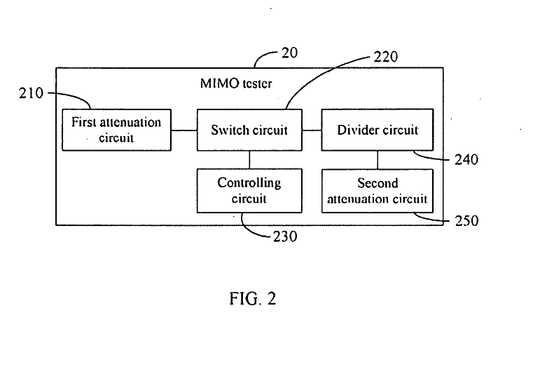

FIG. 2 is a schematic diagram showing one embodiment of functional modules of the MIMO tester 20 in accordance with the present disclosure. The MIMO tester 20 includes a first attenuation circuit 210, a switch circuit 220, a controlling circuit 230, a divider circuit 240, and a second attenuation circuit 250.

The first attenuation circuit 210 and the second attenuation circuit 250 each includes a plurality of resistance attenuators. The first attenuation circuit 210 is electronically connected to the MIMO device 10 in order to adjust an equivalent resistance of the MIMO tester 20 according to different determined test requirements.

The switch circuit 220 is electronically connected to the first attenuation circuit 210. The switch circuit 220 decides if the electronic signals are to be tested by sending the electronic signals to the divider circuit 240 or to the ground. The controlling circuit 230 is electronically connected to the switch circuit 220 for controlling the switch circuit 220. In one embodiment, the controlling circuit 230 may be a general purpose interface bus (GPIB).

The divider circuit 240 receives electronic signals from the MIMO device 10 via the switch circuit 220, divides each electronic signal into a plurality of sub-signals, and sends the sub-signals to at least one test device to test communication parameters of the MIMO device 10. As shown in FIG, 2, the divider circuit 240 is electronically connected to the switch circuit 220 and the second attenuation circuit 250. In one embodiment, the test device is selected from the group comprising the power meter 40 and the spectrum analyzer 50. In one embodiment, the divider circuit 240 is made of printed copper strip, and transmits the received electronic signal to the power meter 40 and the spectrum analyzer 50 to test the communication parameters of the MIMO device 10. In other embodiments, the divider circuit 240 may divide the electronic signal into a plurality of sub-signals in order to test more communication parameters of the MIMO device 10.

The second attenuation circuit 250 adjusts the equivalent resistance of the MIMO tester 20 according to different determined test requirements and is electronically connected to the divider circuit 240.

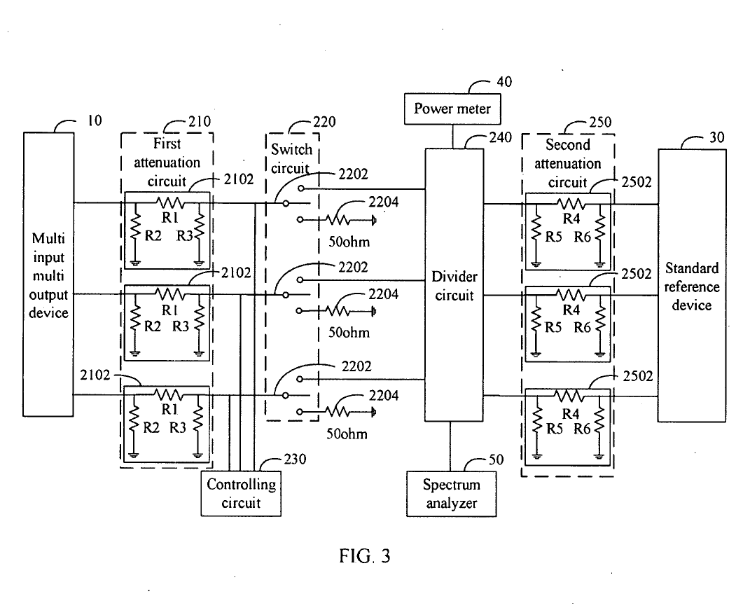

FIG. 3 is a detailed circuit diagram of one embodiment of the MIMO tester 20 in accordance with the present disclosure. The first attenuation circuit 210 includes a plurality of first resistance attenuators 2102. A number of the first resistance attenuators 2102 may be equal to or more than the number of pins of the MIMO device 10. As shown in FIG. 3, the number of the first resistance attenuators 2102 is three, such that the MIMO tester 20 can test the MIMO device 10 having up to three pins. An equivalent resistance of the first resistance attenuators 2102 is alterable according to different determined test requirements.

Each first resistance attenuator 2102 includes a first resistor R1, a second resistor R2, and a third resistor R3. A first end of the first resistor R1 is electronically connected to the MIMO device 10, and a second end of the first resistor R1 is electronically connected to the switch circuit 220. A first end of the second resistor R2 is electronically connected to the a first end of the first resistor R1, and a second end of the second resistor R2 is grounded. A first end of the third resistor R3 is electronically connected to the second end of the first resistor R1, and a second end of the third resistor R3 is grounded. In one embodiment, the resistance of the second resistor R2 is equal to that of the third resistor R3.

The switch circuit 220 includes a plurality of switch elements 2202. In one embodiment, a number of the switch elements 2202 is equal to the number of the first resistance attenuators 2102. The switch element 2202 includes an input end and a first output end and a second output end. The input end is electronically connected to the first attenuation circuit 210. The first output end is electronically connected to the divider circuit 240, and the second output end is grounded via a resistance element 2204. In one embodiment, a resistance of the resistance element 2204 may be approximately 50 Ohms. In one embodiment, the switch element 2202 is electronically connected to the divider circuit 240 if the electronic signal traveling through the switch circuit 220 needs to be tested. The switch element 2202 is electronically connected to ground via the resistance element 2204 if the electronic signal traveling through the switch circuit 220 does not need to be tested, which can improve the return loss of the MIMO tester 20. The controlling circuit 230 controls the switch element 2202 to connect the first attenuation circuit 2102 to the divider circuit 240 or connect the first attenuation circuit 2102 to the resistance element 2204.

The second attenuation circuit 250 includes a plurality of second resistance attenuators 2502. The number of the second resistance attenuators 2502 is equal to that of the first resistance attenuators 2102. The equivalent resistance of the second resistance attenuators 2502 is alterable according to different determined test requirements.

Each second resistance attenuator 2502 includes a fourth resistor R4, a fifth resistor R5, and a sixth resistor R6. A first end of the fourth resistor R4 is electronically connected to the divider circuit 240, and a second end of the fourth resistor R4 is electronically connected to the standard reference device 30. A first end of the fifth resistor R5 is electronically connected to the first end of the fourth resistor R4, and a second end of the fifth resistor R5 is grounded. A first end of the sixth resistor R6 is electronically connected to the second end of the fourth resistor R4, and a second end of the sixth resistor R6 is grounded. In one embodiment, the resistance of the fifth resistor R5 is equal to that of the sixth resistor R6.

When the MIMO device 10 acts as a sender, the standard reference device 30 receives electronic signals from the MIMO device 10 via the MIMO tester 20. When the MIMO device 10 is tested as receiver, the standard reference device 30 sends electronic signals to the MIMO device 10 via the MIMO tester 20.

In one embodiment, the MIMO tester 20 uses a printed circuit to provide a testing environment for the MIMO device 10, bypassing the dividers and attenuators, which reduces the cost of testing. The MIMO tester 20 can improve testing precision because of reducing cable connections between devices.

The description of the present disclosure has been presented for purposes of illustration and description, and is not intended to be exhaustive or limited to the disclosure in the form disclosed. Many modifications and variations will be apparent to those of ordinary skill in the art. Various inventive embodiments were chosen and described in order to best explain the principles of the present disclosure, the practical application, and to enable others of ordinary skill in the art to understand the present disclosure for various embodiments with various modifications as are suited to the particular use contemplated.

What is claimed is:

1. A multiple input multiple output (MIMO) tester for testing a multiple input multiple output device, the MIMO tester comprising:
a first attenuation circuit that adjusts an equivalent resistance of the MIMO tester according to different determined test requirements, wherein the first attenuation circuit is electronically connected to the MIMO device;
a switch circuit comprising a plurality of switch elements, wherein each switch element comprises an input end, a first output end and a second output end, wherein the input end of each of the switch elements is electronically connected to the first attenuation circuit;
a controlling circuit that controls operation of the switch circuit, wherein the controlling circuit is electronically connected to the switch circuit; and
a divider circuit that receives electronic signals from the MIMO device via the switch circuit, divides each electronic signal into a plurality of sub-signals, and sends the sub-signals to at least one test device, wherein the divider circuit is electronically connected to the switch circuit;
wherein the switch circuit decides if the electronic signals are to be tested by sending the electronic signals to the divider circuit or to the ground.

2. The MIMO tester as claimed in claim 1, further comprising a second attenuation circuit that adjusts the equivalent resistance of the MIMO tester according to the different determined test requirements, wherein the second attenuation circuit is electronically connected to the divider circuit.

3. The MIMO tester as claimed in claim 2, wherein the first attenuation circuit comprises a first plurality of resistance attenuators, and wherein the second attenuation circuit comprises a second plurality of resistance attenuators.

4. The MIMO tester as claimed in claim 3, wherein each first resistance attenuator of the first attenuation circuit comprises a first resistor, a second resistor, and a third resistor.

5. The MIMO tester as claimed in claim 4, wherein a first end of the first resistor is electronically connected to the MIMO device, and a second end of the first resistor is electronically connected to the switch circuit.

6. The MIMO tester as claimed in claim 5, wherein a first end of the second resistor is electronically connected to the first end of the first resistor, and a second end of the second resistor is grounded.

7. The MIMO tester as claimed in claim 6, wherein a first end of the third resistor is electronically connected to the second end of the first resistor, and a second end of the third resistor is grounded.

8. The MIMO tester as claimed in claim 3, wherein each second resistance attenuator comprises a fourth resistor, a fifth resistor, and a sixth resistor, wherein a first end of the fourth resistor is electronically connected to the divider circuit, and a second end of the fourth resistor is electronically connected to a standard reference device.

9. The MIMO tester as claimed in claim 8, wherein the standard reference device is a MIMO device with specific communication parameters, wherein the standard reference device is at least one of an access point, a wireless router, or a wireless network card.

10. The MIMO tester as claimed in claim 8, wherein:
a first end of the fifth resistor is electronically connected to the first end of the fourth resistor, and a second end of the fifth resistor is grounded; and
a first end of the sixth resistor is electronically connected to the second end of the fourth resistor, and a second end of the sixth resistor is grounded.

11. The MIMO tester as claimed in claim 3, wherein a number of the switch elements of the switch circuit is equal to a number of the first resistance attenuators and a number of the second resistance attenuators.

12. The MIMO tester as claimed in claim 11, wherein the first output end of the switch element is electronically connected to the divider circuit, and the second output end of the switch element is grounded via a resistance element.

13. The MIMO tester as claimed in claim 12, wherein the resistance of the resistance element is approximately 50 Ohms.

14. The MIMO tester as claimed in claim 1, wherein the controlling circuit is a general purpose interface bus (GPIB) circuit.

15. The MIMO tester as claimed in claim 1, wherein the divider circuit is made of printed copper strip for dividing one electronic signal into a plurality of sub-signals.

16. The MIMO tester as claimed in claim 1, wherein the at least one test device is selected from the group comprising a power meter and a spectrum analyzer.
